(19) United States
(12) Patent Application Publication
(10) Pub. No.: US 2026/0372099 A1
(43) Pub. Date: Nov. 19, 2026

(54) DIE STACK STRUCTURE AND METHOD OF MANUFACTURING THE SAME

(71) Applicant: Advanced Semiconductor Engineering, Inc., Kaohsiung (TW)

(72) Inventor: Nan-Yi WU, Kaohsiung (TW)

(73) Assignee: Advanced Semiconductor Engineering, Inc., Kaohsiung (TW)

(21) Appl. No.: 19/212,599

(22) Filed: May 19, 2025

(51) Int. Cl. H10W 42/00; H10B 80/00; H10D 80/30; H10W 20/20; H10W 74/01; H10W 74/10; H10W 90/00; H10W 90/20; H10W 90/26

(52) U.S. Cl. CPC H10W 42/121; H10B 80/00; H10D 80/30; H10W 20/20; H10W 74/01; H10W 74/121; H10W 90/00; H10W 90/26; H10W 90/297; H10W 90/722

(57) ABSTRACT

The present disclosure provides a die stack structure. The die stack structure includes a lower die, an upper die, a plurality of middle dies between the lower die and the upper die and including a plurality of through-silicon vias (TSVs). The plurality of middle dies include different dielectric measurements. The present disclosure also provides a method for manufacturing a die stack structure.

### BACKGROUND

### 1. Technical Field

The present disclosure relates to a die stack structure.

### 2. Description of the Related Art

3D-stacked memory consists of lower logic die(s), middle die(s), and upper die(s). As the number of layers in the memory increases, the middle dies become sensitive to warping caused by residual stress differences between the center and edge of the wafer. This can negatively impact bonding performance during 3D stacking.

### SUMMARY

In some arrangements, a die stack structure includes a lower die, an upper die, a plurality of middle dies between the lower die and the upper die and including a plurality of through-silicon vias (TSVs). The plurality of middle dies include different dielectric measurements.

In some arrangements, a die stack structure includes a plurality of dies stacked on top of one another and electrically connected, and a plurality of dielectric layers disposed over backside surfaces of the plurality of dies. The plurality of dielectric layers has regions with different dielectric measurements.

In some arrangements, a method for manufacturing a die stack structure includes providing a wafer having a TSV, disposing a dielectric layer over the wafer; and modulating a dielectric measurement of the dielectric layer.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1A illustrates a cross-sectional view of a die in accordance with some arrangements of the present disclosure.

FIG. 1B illustrates a cross-sectional view of a die in accordance with some arrangements of the present disclosure.

FIG. 1C illustrates a cross-sectional view of a die in accordance with some arrangements of the present disclosure.

FIG. 1D illustrates a cross-sectional view of a die in accordance with some arrangements of the present disclosure.

FIG. 1E illustrates a cross-sectional view of a die in accordance with some arrangements of the present disclosure.

FIG. 2 illustrates a top view of a wafer in accordance with some arrangements of the present disclosure.

FIG. 3A illustrates a cross-sectional view of a die stack structure in accordance with some arrangements of the present disclosure.

FIG. 3B illustrates a cross-sectional view of a die stack structure in accordance with some arrangements of the present disclosure.

FIG. 3C illustrates a cross-sectional view of a die stack structure in accordance with some arrangements of the present disclosure.

FIGS. 4A, 4B, 4C, 4D, 4E, 4F, 4F', 4G, and 4H are cross-sections of one or more stages of a method of manufacturing a die stack structure in accordance with some arrangements of the present disclosure.

### DETAILED DESCRIPTION

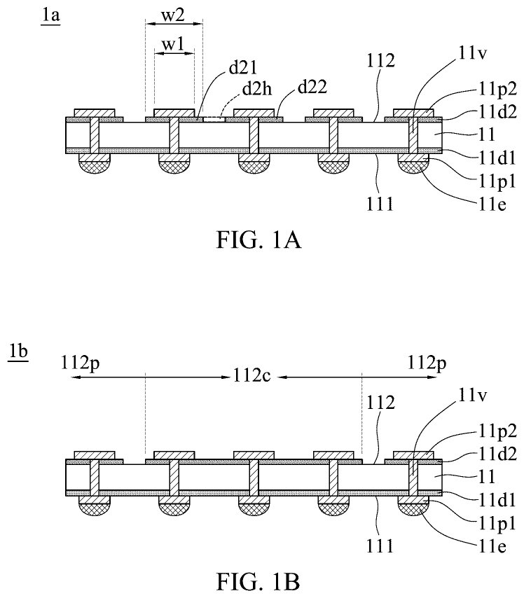

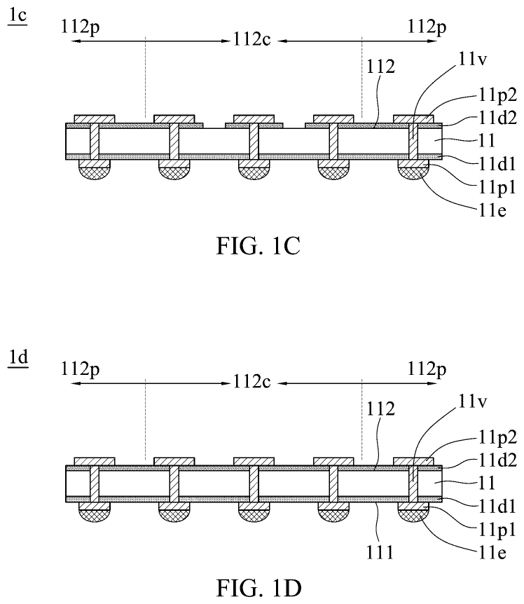

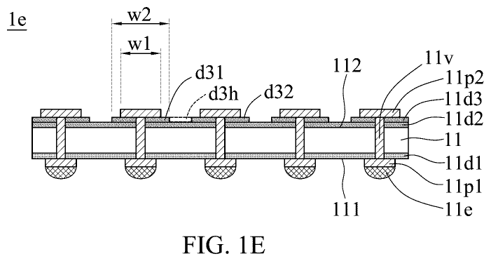

FIG. 1A illustrates a cross-sectional view of a die 1a in accordance with some arrangements of the present disclosure. The die 1a may be or include an unpackaged bare die. The die 1a may be or include a memory die, such as a volatile memory die or non-volatile memory die. For example, the die 1a may be or include a dynamic random access memory (DRAM), but the inventive concept is not limited thereto. For example, the die 1a may be or include other types of components, such as a transceiver die, a processing die, a networking die, etc.

In some arrangements, the die 1a may include a main layer 11, interconnect structures 11v, dielectric layers 11d1, 11d2, conductive pads 11p1, 11p2, and electrical contacts 11e. The main layer 11 may include a silicon layer or other suitable materials, such as silicon carbide, gallium arsenide, aluminum nitride, and sapphire. The main layer 11 may include a surface 111 and a surface 112 opposite to the surface 111. The surface 111 may be an active surface, a front surface, or a front side. The surface 112 may be a backside surface or a backside.

The interconnect structures 11v may include conductive vias, such as through-silicon vias (TSVs). The interconnect structures 11v may penetrate through the main layer 11. For example, the interconnect structures 11v may have an elongation direction that is oriented substantially perpendicular to the surface 111 and/or the surface 112 of the main layer 11. For example, the interconnect structures 11v may extend between the surface 111 and the surface 112. For example, the interconnect structures 11v may extend beyond the surface 111 and the surface 112. For example, the interconnect structures 11v may extend beyond the boundaries of the surface 111 and the surface 112.

The dielectric layer 11d1 may be disposed over the surface 111. The interconnect structures 11v may be partially surrounded by the dielectric layer 11d1. The dielectric layer 11d1 may expose portions of the interconnect structures 11v. The conductive pads 11p1 may be disposed over the dielectric layer 11d1. The conductive pads 11p1 may contact the exposed portions of the interconnect structures 11v.

The dielectric layer 11d1 may cover a region of the surface 111 between two of the conductive pads 11p1. For example, the dielectric layer 11d1 may continuously cover a region of the surface 111 between two of the conductive pads 11p1. For example, the dielectric layer 11d1 may cover the entire surface 111, except for the exposed portions of the interconnect structures 11v. For example, the dielectric layer 11d1 may have an unpatterned area between two of the conductive pads 11p1.

The dielectric layer 11d2 may be disposed over the surface 112. The interconnect structures 11v may be partially surrounded by the dielectric layer 11d2. The dielectric layer 11d2 may expose portions of the interconnect structures 11v. The conductive pads 11p2 may be disposed over the dielectric layer 11d2. The conductive pads 11p2 may contact the exposed portions of the interconnect structures 11v.

The dielectric layer 11d2 may be patterned. The dielectric layer 11d2 may not continuously cover the surface 112. The dielectric layer 11d2 may have one or more openings d2h to expose the surface 112. The opening d2h may be a gap or void. The opening d2h may have a symmetric profile.

The surface 112 may be exposed through the opening d2h. A region of the surface 112 between two of the conductive pads 11p2 may be at least partially exposed or uncovered by the dielectric layer 11d2.

For example, the dielectric layer 11d2 may have a segment d21 and a segment d22 spaced apart from the segment d21 when viewed in a cross-sectional perspective. The segment d21 and the segment d22 may be separated by the opening d2h when viewed in a cross-sectional perspective. The opening d2h may abut the segment d21 and the segment d22.

Despite this separation, the segments d21 and d22 may not be entirely isolated from one another. For example, the segments d21 and d22 may be interconnected through an additional portion of the dielectric layer 11d2.

The conductive pad 11p2 may have a dimension (such as a width) w1 and the segment d21 of the dielectric layer 11d2 may have a dimension (such as a width) w2 substantially greater than the dimension w1. In some arrangements, the dimension w2 may be substantially equal to the dimension w1.

The dielectric layer 11d2 and the dielectric layer 11d1 may have different or varying dielectric profiles or measurements. For example, the coverage of the dielectric layer 11d2 on the surface 112 may be substantially less than the coverage of the dielectric layer 11d1 on the surface 111. For example, the area of the surface 112 covered or occupied by the dielectric layer 11d2 may be substantially less than the area of the surface 111 covered or occupied by the dielectric layer 11d1.

For example, the amount of dielectric material on the surface 112 may be substantially less than the amount of dielectric material on the surface 111. For example, the specific quantity (such as in a weight unit or a volume unit) of the dielectric layer 11d2 may be substantially less than the specific quantity of the dielectric layer 11d1. For example, the amount of dielectric material between two conductive pads 11p2 on the surface 112 may be different from the amount of dielectric material between two conductive pads 11p1 on the surface 111.

In some arrangements, the dielectric layer 11d2 and the dielectric layer 11d1 may not overlap in a direction substantially perpendicular to the surface 111 and/or the surface 112. For example, a region of the main layer 11 may be covered by the dielectric layer 11d1, while an opposite region of the main layer 11 may be exposed by the dielectric layer 11d2.

In some arrangements, the interconnect structures 11v, and the conductive pads 11p1 and 11p2 may each include a conductive material such as a metal or metal alloy. Examples of the conductive materials include gold (Au), silver (Ag), copper (Cu), platinum (Pt), palladium (Pd), other metals or alloys, or a combination of two or more of these. In some arrangements, the interconnect structures 11v, and the conductive pads 11p1 and 11p2 may each include a metal-containing feature.

In some arrangements, the dielectric layers 11d1 and 11d2 may also be referred to as insulation layers or interlayer dielectric (ILD) layers. In some arrangements, the dielectric layers 11d1 and 11d2 may each include silicon dioxide, carbon-doped oxide, organosilicate glasses, an epoxy resin with fillers, a molding compound (e.g., an epoxy molding compound or another type of molding compound), Ajinomoto build-up film (ABF), etc.

One or more electrical contacts 11e may be disposed over the conductive pads 11p1 for providing electrical connections. The conductive pads 11p1 and 11p2, and the interconnect structures 11v may be electrically connected with the electrical contacts 11e. In some arrangements, the electrical contacts 11e may include solder balls or solder bumps, such as controlled collapse chip connection (C4) bumps, a ball grid array (BGA) or a land grid array (LGA).

FIG. 1B illustrates a cross-sectional view of a die 1b in accordance with some arrangements of the present disclosure. The die 1b is similar to the die 1a in FIG. 1A except that the distribution of the dielectric layer 11d2 across the surface 112 may be non-uniform.

For example, the surface 112 may include a central portion 112c and a peripheral portion 112p. The central portion 112c may have more regions covered by the dielectric layer 11d2 than the peripheral portion 112p does. For example, the dielectric layer 11d2 may continuously cover a region of the central portion 112c between two of the conductive pads 11p2. The dielectric layer 11d2 may expose a region of the peripheral portion 112p between two of the conductive pads 11p2. The central portion 112c may be a dielectric-rich region and the peripheral portion 112p may be a dielectric-poor region.

FIG. 1C illustrates a cross-sectional view of a die 1c in accordance with some arrangements of the present disclosure. The die 1c is similar to the die 1a in FIG. 1A except that the distribution of the dielectric layer 11d2 across the surface 112 may be non-uniform.

For example, the peripheral portion 112p may have more regions covered by the dielectric layer 11d2 than the central portion 112c does. For example, the dielectric layer 11d2 may continuously cover a region of the peripheral portion 112p between two of the conductive pads 11p2. The dielectric layer 11d2 may expose a region of the central portion 112c between two of the conductive pads 11p2. The peripheral portion 112p may be a dielectric-rich region and the central portion 112c may be a dielectric-poor region.

In some arrangements, the openings d2h may have asymmetrical arrangement over the surface 112.

FIG. 1D illustrates a cross-sectional view of a die 1d in accordance with some arrangements of the present disclosure. The die 1d is similar to the die 1a in FIG. 1A except that the dielectric layer 11d2 may continuously cover a region of the surface 112 between two of the conductive pads 11p1. For example, the coverage of the dielectric layer 11d2 on the surface 112 may be substantially equal to the coverage of the dielectric layer 11d1 on the surface 111. For example, the amount of dielectric material on the surface 112 may be substantially equal to the amount of dielectric material on the surface 111.

In some arrangements, the coverage of the dielectric layer 11d2 on the die 1d may be substantially greater than the coverage of the dielectric layer 11d2 on the die 1a. For example, the area of the surface 112 covered or occupied by the dielectric layer 11d2 on the die 1d may be substantially greater than the area of the surface 112 covered or occupied by the dielectric layer 11d2 on the die 1a.

In some arrangements, the amount of dielectric material of the die 1d may be substantially greater than the amount of dielectric material of the die 1a. For example, the specific quantity (such as in a weight unit or a volume unit) of the dielectric layer 11d2 of the die 1d may be substantially greater than the specific quantity of the dielectric layer 11d2 of the die 1a. For example, the amount of dielectric material between two conductive pads 11p2 on the surface 112 of the die 1d may be substantially greater than the amount of dielectric material between two conductive pads 11p1 on the surface 112 of the die 1a.

FIG. 1E illustrates a cross-sectional view of a die 1e in accordance with some arrangements of the present disclosure. The die 1e is similar to the die 1d in FIG. 1D except that the die 1e further includes a dielectric layer 11d3 disposed over the dielectric layer 11d2. The dielectric layer 11d3 and the dielectric layer 11d2 may have the same material or different materials.

The dielectric layer 11d3 may be patterned. The dielectric layer 11d3 may not continuously cover the surface 112. The dielectric layer 11d3 may have one or more openings d3h to expose the dielectric layer 11d2. The opening d3h may be a gap or void. The dielectric layer 11d2 may be exposed through the opening d3h. A region of the dielectric layer 11d2 between two of the conductive pads 11p2 may be at least partially exposed or uncovered by the dielectric layer 11d3.

For example, the dielectric layer 11d3 may have a segment d31 and a segment d32 spaced apart from the segment d31 when viewed in a cross-sectional perspective. The segment d31 and the segment d32 may be separated by the opening d3h when viewed in a cross-sectional perspective. Despite this separation, the segments d31 and d32 may not be entirely isolated from one another. For example, the segments d31 and d32 may be interconnected through an additional portion of the dielectric layer 11d3.

The segment d31 of the dielectric layer 11d3 may have a dimension (such as a width) w2 substantially greater than the dimension w1. In some arrangements, the dimension w2 may be substantially equal to the dimension w1.

The coverage of the dielectric layer 11d3 on the surface 112 may be different from the coverage of the dielectric layer 11d2 on the surface 112. For example, the coverage of the dielectric layer 11d3 on the surface 112 may be substantially less than the coverage of the dielectric layer 11d2 on the surface 112. For example, the amount of dielectric material of the dielectric layer 11d3 may be substantially less than the amount of dielectric material of the dielectric layer 11d2.

In some arrangements, the dielectric layer 11d3 and the dielectric layer 11d2 may not overlap in a direction substantially perpendicular to the surface 111 and/or the surface 112.

In some arrangements, the thickness of the dielectric layers 11d3 and 11d2 may be substantially greater than the thickness of the dielectric layers 11d1. In some arrangements, the amount of dielectric material on the surface 112 may be substantially greater than the amount of dielectric material on the surface 111.

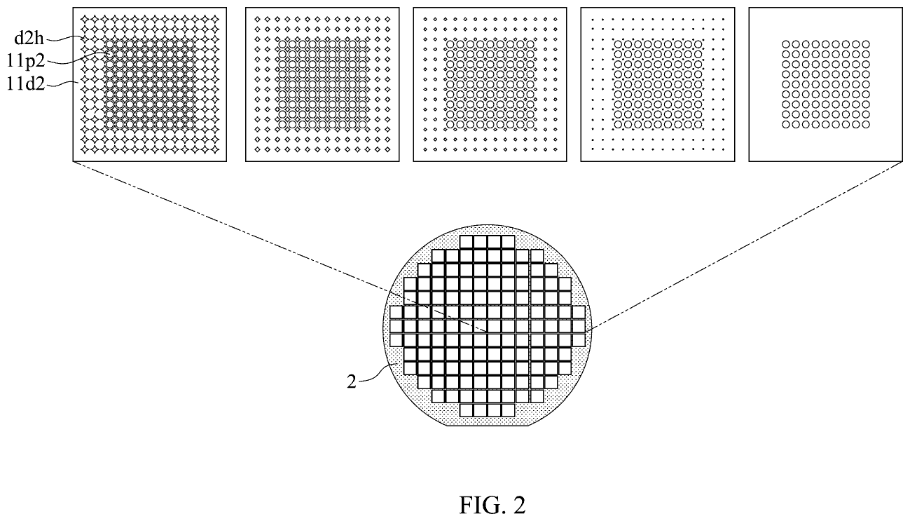

FIG. 2 illustrates a top view of a wafer 2 in accordance with some arrangements of the present disclosure. In some arrangements, the wafer 2 may include a plurality of dies, such as the dies 1a, 1b, 1c, 1d, and 1e. During the singulation operation (or cutting operation), cutting may be performed along the scribe lines, resulting in the division of the wafer 2 into a plurality of dies.

The dielectric distribution across the wafer 2 may be non-uniform. For example, the wafer 2 may include regions with a varying amount of dielectric material. For example, the wafer 2 may include a dielectric-rich region and a dielectric-poor region. For example, some regions of the wafer 2 may have a higher dielectric concentration, while others have less.

In some arrangements, the amount of dielectric material near the center of wafer 2 may be greater than the amount of dielectric material farther from the center of wafer 2. In some arrangements, the amount of dielectric material on the wafer 2 may gradually decrease from the center to the periphery. For example, the enlarged top views of the dielectric layer 11d2 may define the openings d2h among the conductive pads 11p2. The openings d2h are represented by diamond shapes, while the conductive pads 11p2 are represented by circles. The number or density of the conductive pads 11p2 may remain substantially the same from the center to the periphery. In contrast, the number or density of the openings d2h may vary, for example, by decreasing from the center to the periphery of the wafer 2.

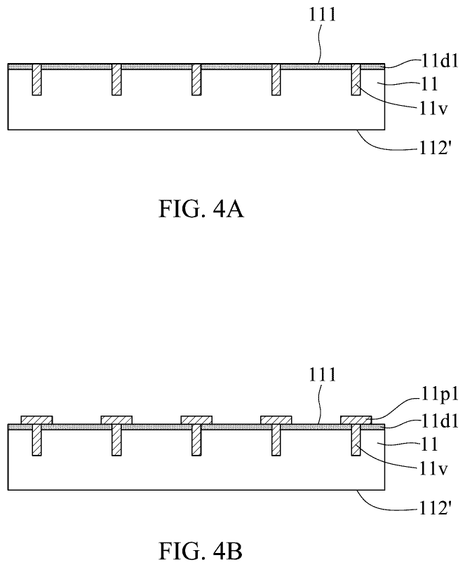

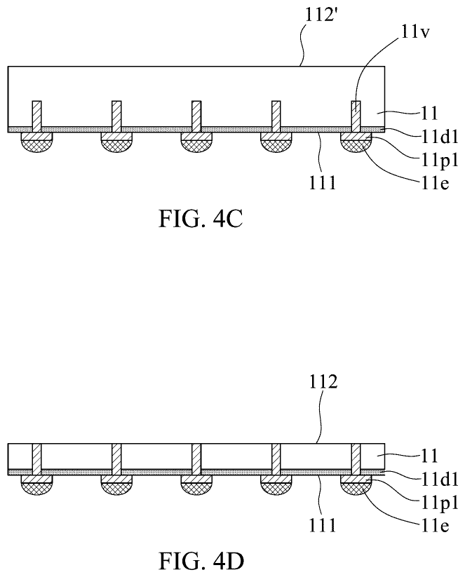

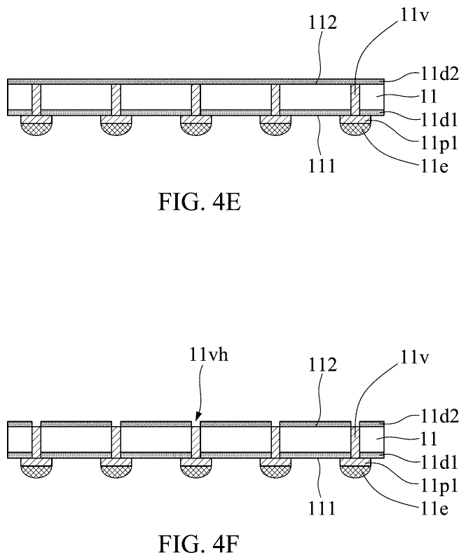

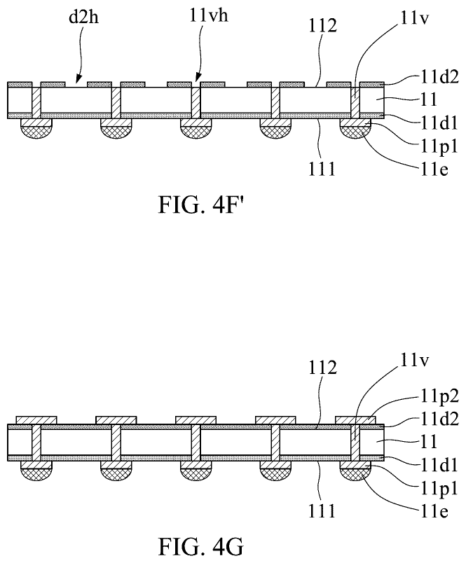

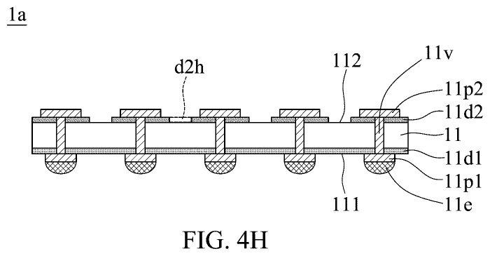

During the deposition of dielectric layer 11d2 (e.g., as shown in FIG. 4E), techniques such as chemical vapor deposition (CVD) or plasma-enhanced CVD (PECVD) may be employed. Residual stress may arise from various factors during deposition and cooling, resulting in internal stresses within the dielectric layer 11d2, which may cause warpage. For example, the curvature direction of the center of the wafer may be different from the curvature direction of the periphery of the wafer. For example, peripheral warpage may be more pronounced than that at the center, and the height level difference between the periphery and the center may exceed approximately 50 micrometers. For example, the wafer may have an inflection point. After the singulation operation, the dies may exhibit a different curvature direction and/or degree of warpage, which can adversely affect bonding performance in 3D stacking. For example, the outermost memory die may exhibit a greater degree of warpage than the other dies.

According to some arrangements of the present disclosure, the present invention mitigates the warpage issue by selectively adjusting or modulating dielectric profiles or measurements across the wafer, thereby decreasing the residual stress and warping. For example, the dies cut from the wafer 2 may exhibit varying dielectric profiles or measurements—such as differences in coverage, quantity, distribution, and thickness—while maintaining a substantially consistent curvature direction and/or degree of warpage. For instance, the degree of warpage could be measured and found to be below a predetermined threshold, indicating that it falls within an acceptable range. The present invention enhances the uniformity and stability of the dies during subsequent processing steps.

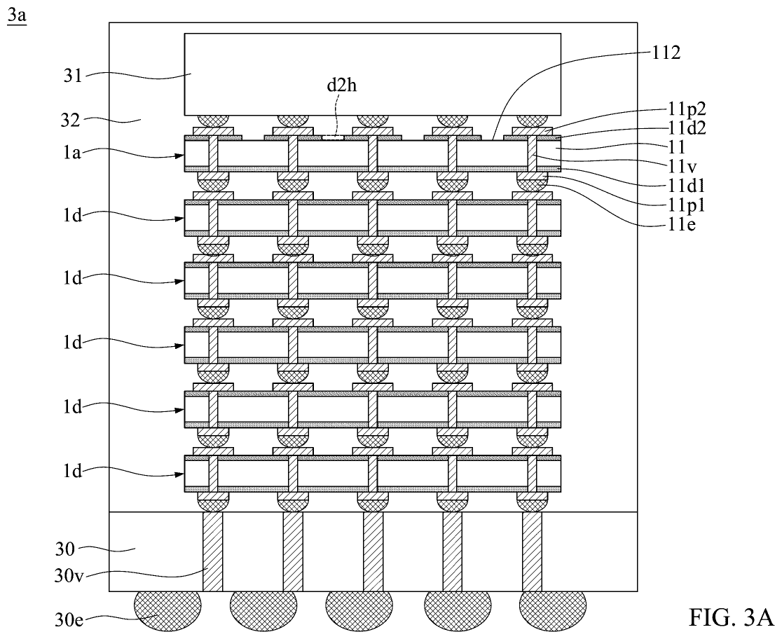

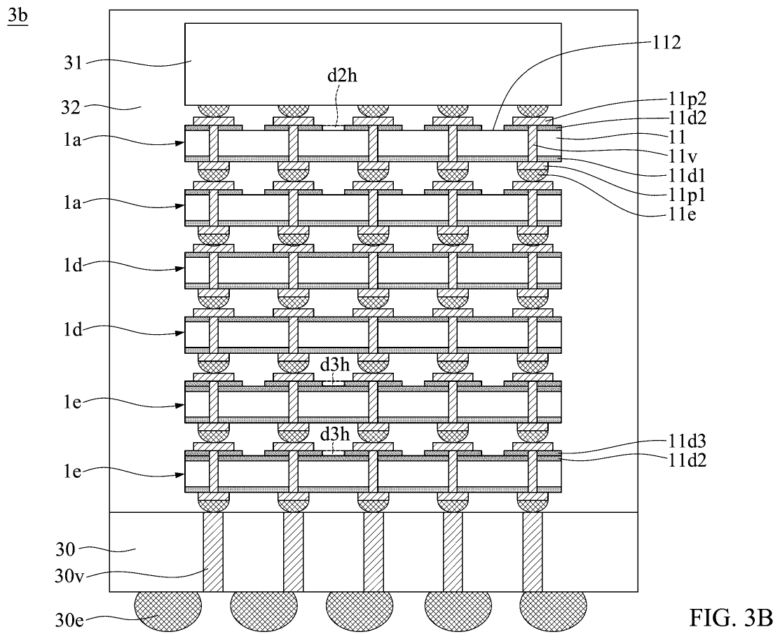

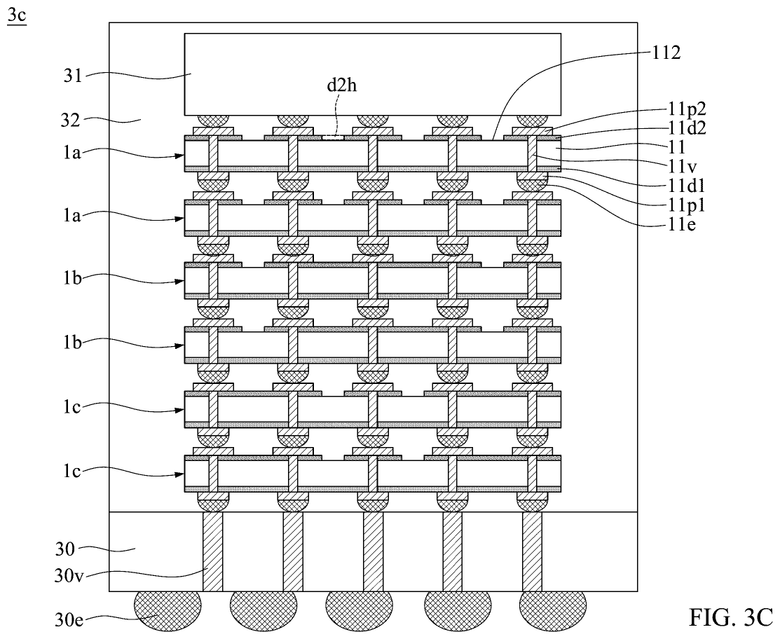

FIG. 3A illustrates a cross-sectional view of a die stack structure 3a in accordance with some arrangements of the present disclosure. In some arrangements, the die stack structure 3a may be or include a memory stack, such as a stack of memory dies. The memory stack may be 3D-stacked memory, such as a high bandwidth memory (HBM) stack, a hybrid memory cube (HMC), or the like, that includes multiple memory dies.

The die stack structure 3a may include dies 1a, 1d, dies 30, 31, and an encapsulant 32. The dies 1a, 1d, 30, and 31 may be stacked on top of one another and electrically connected.

The die 30 may also be referred to as a lower die or a logic die. The die 30 may include interconnect structures 30v, which may be TSVs. The interconnect structures 30v may penetrate through the die 30.

The die 30 may include control logic for managing memory operations. For example, the die 30 may be configured to communicate with an external controller or a host system, receive commands, addresses, and data, and relay these commands, addresses, and data to the other dies in the die stack structure 3a. The die 30 may communicate with the external controller through one or more electrical contacts 30e located on its surface. In some arrangements, the electrical contacts 30e may include an input/output architecture. In some arrangements, the electrical contacts 30e may connect to a voltage rail.

In some arrangements, the commands are the instructions for memory operations, such as reading from or writing to memory, initializing processes, or managing data flow. In some arrangements, the addresses specify where in memory those operations should occur, and data is the information being manipulated during those operations. In the memory operations, data is what is being read from or written to the memory locations specified by the addresses.

The dies 1a and 1d may be disposed between the die 30 and the die 31. The dies 1a and 1d may also be referred to as middle dies. The warpage measurement of the middle dies of the die stack structure 3a may be acceptable. The dies 1a and 1d may have an alignment pattern. Each of the dies 1a and 1d may be configured to store data and can be accessed independently, enabling parallel data access and improving overall performance. The die 31 may also be referred to as an upper die or a top die. In some arrangements, the die 31 may be configured to store data and help increase the overall memory capacity. Additionally, the die 31 may be configured to perform specific functions such as caching or buffering, or it may include additional features or optimizations that enhance performance or power efficiency.

The encapsulant 32 may include an epoxy resin with fillers, a molding compound (e.g., an epoxy molding compound or another type of molding compound), a polyimide, a phenolic compound or material, a material with a silicone dispersed therein, or a combination thereof. In some arrangements, the encapsulant 32 may include a material different from that of the dielectric layers of the dies 1a and 1d. The encapsulant 32 may contact or cover the exposed portions of the surface 112 of the die 1a. The encapsulant 32 may fill the opening d2h. The encapsulant 32 may be configured as a venting blocker.

The middle dies of the die stack structure 3a may have different or varying dielectric profiles or measurements. For example, the coverage of the dielectric layers 11d2 of the middle dies in the die stack structure 3a may vary.

For example, the die stack structure 3a may include dies with a varying amount of dielectric material. For example, the die stack structure 3a may include a dielectric-rich die (such as the die 1d) and a dielectric-poor die (such as the die 1a).

For example, the amount of dielectric material of the middle dies in the die stack structure 3a may vary. For example, the specific quantity (such as in a weight unit or a volume unit) of the dielectric layer 11d2 of the middle dies in the die stack structure 3a may vary. For example, the amount of dielectric material between two conductive pads of the middle dies in the die stack structure 3a may vary.

The dielectric distribution of the die stack structure 3a may be non-uniform. For example, the dielectric distribution along the stacking direction may be non-uniform. For example, in the orientation in which the middle dies are arranged, a measurement of dielectric layers 11d2 of the middle dies vary from one layer to another.

In some arrangements, the die stack structure 3a may have at least one die with a patterned dielectric layer. For example, the die stack structure 3a may have at least one die 1a. In some arrangements, the die stack structure 3a may have more dies 1a. The die 1a may be disposed on top of the dies 1d. This is because, during the molding operation of the encapsulant 32, the encapsulant 32 exhibits better fluidity on the top of the middle dies. This fluidity can lead to more efficient filling of the openings or cavities. Therefore, positioning die 1a directly on top of dies 1d could potentially optimize the molding operation by facilitating the complete filling of the openings present in die 1a. This strategic arrangement may help ensure that the encapsulant 32 flows more freely and uniformly into the die 1a, thereby improving the overall quality and performance of the final molded product.

FIG. 3B illustrates a cross-sectional view of a die stack structure 3b in accordance with some arrangements of the present disclosure. The die stack structure 3b is similar to the die stack structure 3a in FIG. 3A except that the die stack structure 3b includes two dies 1a, two dies 1d, and two dies 1e.

The dielectric distribution along the stacking direction may vary either gradually or non-gradually. In some arrangements, the amount of dielectric material near the die 30 may be greater than the amount of dielectric material farther from the die 30. In some arrangements, the amount of dielectric material may decrease from the die 30 to the die 31. In some arrangements, the die stack structure 3b may include a dielectric-rich die (such as the die 1e) and a dielectric-poor die (such as the die 1a).

FIG. 3C illustrates a cross-sectional view of a die stack structure 3c in accordance with some arrangements of the present disclosure. The die stack structure 3c is similar to the die stack structure 3a in FIG. 3A except that the die stack structure 3c includes two dies 1a, two dies 1b, and two dies 1c.

The dielectric distribution of each of the middle dies in the die stack structure 3c may vary. For example, there may be more openings in the dies 1a than in the dies 1b and 1c. For example, the openings in the dies 1b may be present on the periphery, and the openings in the dies 1c may be present at the center. For example, the openings in the dies 1b and the openings in the dies 1c may be misaligned. The misalignment values of the middle dies in the die stack structure 3c may vary. For example, the estimated misalignment values of the middle dies in the die stack structure 3c may vary within an acceptable range.

It should be noted that while the die stack structures 3a, 3b, and 3c are presented as specific examples, the scope of the present invention is not confined to this particular configuration. In fact, the number and the relative location of the distinct dies (such as the dies 1a, 1b, 1c, 1d, and 1e) can be adjusted to meet various requirements and specifications, allowing for flexibility and adaptability in different applications.

FIGS. 4A, 4B, 4C, 4D, 4E, 4F, 4F', 4G, and 4H are cross-sections of one or more stages of a method of manufacturing a die stack structure in accordance with some arrangements of the present disclosure.

Referring to FIG. 4A, a wafer may be provided. The wafer may include a plurality of dies, such as the dies 1a, 1b, 1c, 1d, and 1e. The dies 1a, 1b, 1c, 1d, and 1e may be subjected to similar or identical processes in the manufacturing method. For conciseness and clarity, a portion of the wafer—specifically, the die 1a—is presented as a specific example. The main layer 11 of the die 1a may include the surface 111 and a surface 112′ opposite to the surface 111. The dielectric layer 11d1 may be disposed over the surface 111. The interconnect structures 11v may be partially surrounded by the dielectric layer 11d1. The dielectric layer 11d1 may expose portions of the interconnect structures 11v.

Referring to FIG. 4B, the conductive pads 11p1 may be disposed over the dielectric layer 11d1. The conductive pads 11p1 may contact the exposed portions of the interconnect structures 11v. In some arrangements, the conductive material may be disposed through, for example, physical vapor deposition (PVD), such as sputtering or spray coating. In some arrangements, the conductive material may be disposed through CVD or plating.

Referring to FIG. 4C, the electrical contacts 11e may be disposed over the conductive pads 11p1. The wafer may be flipped.

Referring to FIG. 4D, a portion of main layer 11 may be removed by, for example, a grinding operation. The interconnect structures 11v may be partially exposed from the surface 112 of the main layer 11.

Referring to FIG. 4E, the dielectric layer 11d2 may be disposed over the surface 112 and cover the interconnect structures 11v. The dielectric layer 11d2 may be disposed by CVD, PECVD, or other feasible techniques. In some arrangements, multiple dielectric layers may be disposed. For example, the dielectric layer 11d3 as shown in FIG. 1E can be additionally formed over the dielectric layer 11d2.

Referring to FIG. 4F, the dielectric layer 11d2 may be patterned to form openings 11vh exposing the interconnect structures 11v.

Referring to FIG. 4G, the conductive pads 11p2 may be disposed over the dielectric layer 11d2. The conductive pads 11p2 may contact the exposed portions of the interconnect structures 11v.

Referring to FIG. 4H, the dielectric profiles or measurements across the wafer may be selectively adjusted or modulated. For example, the dielectric layer 11d2 may be patterned to form the openings d2h exposing the surface 112. The openings d2h may be formed through, for example, a lithography operation. The locations, numbers, and sizes of the openings d2h may be adjusted according to the material properties, processing environment, or other factors that may affect residual stress. For example, a target processing speed for patterning the dielectric layer 11d2 may be adjusted. The openings d2h may be configured to decrease the residual stress. The dielectric layer 11d2 may be configured as a stress relief structure, a warpage relief structure, or a warpage relief material. The dielectric layer 11d2 may be configured as an interior stress relief structure, and the encapsulant 32 can be an exterior stress relief structure. The dielectric layer 11d2 may be configured as a damper, such as an active mass damper. The dielectric layer 11d2 may be configured to reduce a loading effect.

In some arrangements, the dielectric profiles or measurements across the wafer may be selectively adjusted or modulated by additionally disposing dielectric material over the dielectric layer 11d2.

In some arrangements, the openings d2h and the openings 11vh may be formed in the same operation. For example, referring to FIG. 4F', after the operation in FIG. 4E, the dielectric layer 11d2 may be patterned to form the openings d2h and the openings 11vh. Then, the conductive pads 11p2 may be disposed over the openings 11vh to connect the interconnect structures 11v.

In some arrangements, the openings d2h and the openings 11vh may have different aspect ratios.

Next, a singulation operation may be performed. The wafer may be singulated or separated into a plurality of individual dies in a singulation operation. In some arrangements, the singulation operation may be applied using a saw blade or laser cutting tool.

The dies cut from the wafer may have different dielectric quantities, distributions, and/or thicknesses. However, since the amount of dielectric material in the dielectric layer 11d2 is selectively adjusted, the dies exhibit a consistent curvature direction and/or degree of warpage. Therefore, when stacking the dies, the bonding performance of the dies in the die stack structure can be improved.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and the lowest point of the surface is no greater than 5 μm, no greater than 2 μm, no greater than 1 μm, or no greater than 0.5μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amount, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A die stack structure, comprising:
a lower die;
an upper die; and
a plurality of middle dies between the lower die and the upper die and including a plurality of through-silicon vias (TSVs);
wherein the plurality of middle dies include different dielectric measurements.

2. The die stack structure of claim 1, wherein the different dielectric measurements include at least one of the following: coverage, amount, distribution, and thickness of dielectric material.

3. The die stack structure of claim 1, wherein the plurality of middle dies include a substantially consistent curvature direction.

4. The die stack structure of claim 1, wherein the plurality of middle dies include a substantially consistent degree of warpage.

5. The die stack structure of claim 1, wherein a first middle die of the plurality of middle dies includes a main layer, the TSVs penetrating through the main layer, and a dielectric layer disposed over a surface of the main layer, wherein the surface of the main layer is partially exposed through an opening of the dielectric layer.

6. The die stack structure of claim 5, further comprising an encapsulant contacting an exposed portion of the surface of the main layer.

7. The die stack structure of claim 1, wherein the plurality of middle dies include a dielectric-rich die and a dielectric-poor die, and the dielectric-rich die is closer to the lower die than the dielectric-poor die is.

8. The die stack structure of claim 7, wherein the dielectric-rich die includes a main layer, the TSVs penetrating through the main layer, a first dielectric layer disposed over the main layer, and a second dielectric layer disposed over the first dielectric layer, wherein a surface of the second dielectric layer is partially exposed through an opening of the first dielectric layer.

9. A die stack structure, comprising:
a plurality of dies stacked on top of one another and electrically connected; and
a plurality of dielectric layers disposed over backside surfaces of the plurality of dies;
wherein the plurality of dielectric layers has regions with different dielectric measurements.

10. The die stack structure of claim 9, wherein the different dielectric measurements include at least one of the following: coverage, amount, distribution, and thickness of dielectric material.

11. The die stack structure of claim 9, wherein the plurality of dies include a substantially consistent curvature direction.

12. The die stack structure of claim 9, wherein the plurality of dies include a substantially consistent degree of warpage.

13. The die stack structure of claim 9, wherein at least one of the backside surfaces of the plurality of dies is exposed.

14. The die stack structure of claim 13, further comprising an encapsulant contacting an exposed portion of the one of the backside surfaces.

15. A method for manufacturing a die stack structure, comprising:
providing a wafer having a through-silicon via (TSV);
disposing a dielectric layer over the wafer; and
modulating a dielectric measurement of the dielectric layer.

16. The method of claim 15, wherein modulating the dielectric measurement includes patterning the dielectric layer.

17. The method of claim 15, wherein modulating the dielectric measurement includes forming a first opening in the dielectric layer to expose a portion of the wafer.

18. The method of claim 17, wherein the first opening is configured to decrease a residual stress of the dielectric layer.

19. The method of claim 15, wherein disposing the dielectric layer includes covering the TSV with the dielectric layer.

20. The method of claim 15, further comprising:
singulating the wafer into a plurality of dies; and
stacking the plurality of dies.
